(19) United States
(12) Patent Application Publication
(10) Pub. No.: US 2002/0072237 A1
(43) Pub. Date: Jun. 13, 2002

(54) Method for unpatterned resist etch back of shallow trench isolation refill insulator

(76) Inventors: Christopher Mark Bowles, Plano, TX (US); Stanton Petree Ashburn, McKinney, TX (US); Gregory Boyd Shinn, Dallas, TX (US); Daniel S. Criswell, Dallas, TX (US)

Correspondence Address: TEXAS INSTRUMENTS INCORPORATED, P O BOX 655474, M/S 3999, DALLAS, TX, 75265

(21) Appl. No.: 09/732,468

(22) Filed: Dec. 7, 2000

Related U.S. Application Data
(60) Provisional application No. 60/171,694, filed on Dec. 22, 1999.

(51) Int. Cl. H01L 21/302; H01L 21/461

(52) U.S. Cl. 438/690

(57) ABSTRACT

A method for forming shallow trench isolation structures is provided that includes forming a plurality of isolation trenches (32) in a substrate (10) where the isolation trenches (32) separate active areas (18). An insulation layer (44) is formed outwardly from the substrate (10) with the insulation layer (44) filling the isolation trenches (32) and covering the active areas (18). A planarization layer (46) is formed outwardly from the insulation layer (44). The planarization layer (46) and the insulation layer (44) are removed together at a substantially even rate down to a polish stop (14) outward from the active areas (18).

### BACKGROUND OF THE INVENTION

Semiconductor components must be properly isolated from one another to function properly. For example, the state and conductance of individual transistors can only be controlled if proper isolation exists among the transistors. If not, leakage currents may occur, causing power dissipation, noise-margin degradation, and voltage shift on dynamic nodes. Additionally, cross talk among transistors can destroy the logic state of a gate.

In the past, LOCOS field oxide (locally oxidized field oxide areas) have been used to isolate components of an integrated circuit. LOCOS field oxide is typically formed by first patterning and etching a nitride film on a substrate to form windows over the isolation area. The substrate is then subjected to thermal treatment to grow field oxide in the isolation areas. LOCOS field oxide is not scalable below 0.5 microns. Accordingly, LOCOS field oxide does not provide a satisfactory isolation system for sub 0.5 micron applications.

More recently, shallow trench isolation structures have been used for sub 0.5 micron applications. Typically, a narrow trench is formed in a substrate. The trench may be filled with a deposited insulating material such as high density plasma oxide deposition or CVD oxide deposition. Excess insulating material deposited on the substrate should be removed to expose active areas of the substrate.

One method of removing excess insulating material from the substrate is to use a chemical mechanical polishing (CMP) process to polish away excess insulating material. The CMP process, however, may lead to excessive polishing (dishing) of large field areas between devices and polishing through isolated structures on the active areas on which the devices will be fabricated. To solve these problems, a resist and etch process has been used followed by a CMP process. A mask is used to cover field areas with a resist material. An oxygen plasma etch is then used to etch away refill oxide over the active areas. Once the active areas are exposed, a CMP process is used to remove the remaining refill oxide down to a nitride layer above the active areas. Although the aforementioned process addresses problems related to excessive polishing of large field areas and isolated active areas, this process requires the use of prohibitively expensive machines and processes.

### SUMMARY OF THE INVENTION

From the foregoing, it may be appreciated that a need has arisen for an improved method for unpatterned resist etch back of shallow trench isolation refill insulator. In accordance with the present invention, an improved method for unpatterned resist etch back of shallow trench isolation refill insulator is provided that substantially eliminates or reduces disadvantages and problems associated with conventional methods of forming shallow etch isolation structures. More particularly, the present invention provides a planarization layer and a process that allows these shallow trench isolation structures to be formed without photolithography thereby reducing costs.

According to an embodiment of the present invention, there is provided a method for forming shallow trench isolation structures that includes forming a plurality of isolation trenches in the substrate where the isolation trenches separate active areas of the substrate. The method next provides for forming an insulation layer outwardly from the substrate with the insulation layer filling the isolation trenches and covering the active areas. The method next provides for forming a planarization layer outwardly from the insulation layer. The method next provides for removing the planarization layer and the insulation layer together at a substantially even rate down to a polish stop for the active areas.

The present invention provides various technical advantages over conventional methods for forming shallow trench isolation structures. For example, one technical advantage is providing an unpatterned resist etch back of shallow trench isolation refill insulator that results in significantly reduced costs of fabrication for these shallow trench isolation structures. Other technical advantages may be readily apparent to one skilled in the art from the following figures, description, and claims.

### BRIEF DESCRIPTION OF THE DRAWINGS

For a more complete understanding of the present invention and the advantages thereof, reference is now made to the following description taken in conjunction with the accompanying drawings, wherein like reference numbers represent like parts, in which:

FIGS. 1A-1F are a series of cross-sectional diagrams illustrating an unpatterned resist etch back of shallow trench isolation refill oxide in accordance with one embodiment of the present invention.

### DETAILED DESCRIPTION OF THE INVENTION

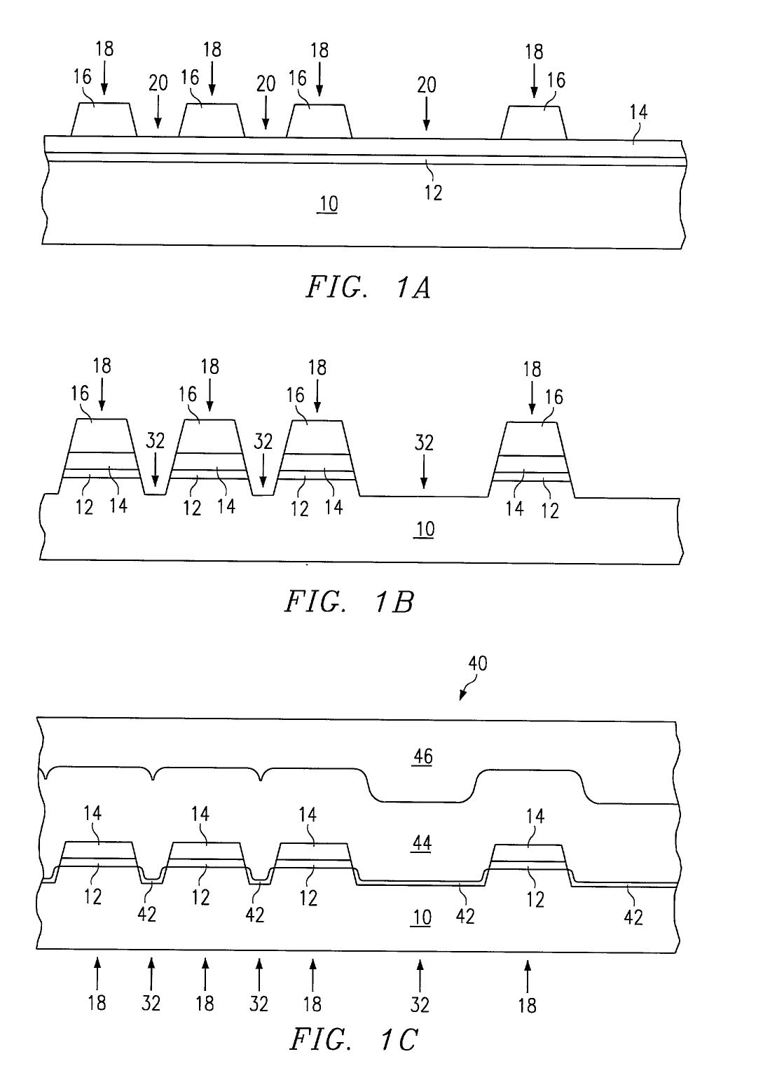

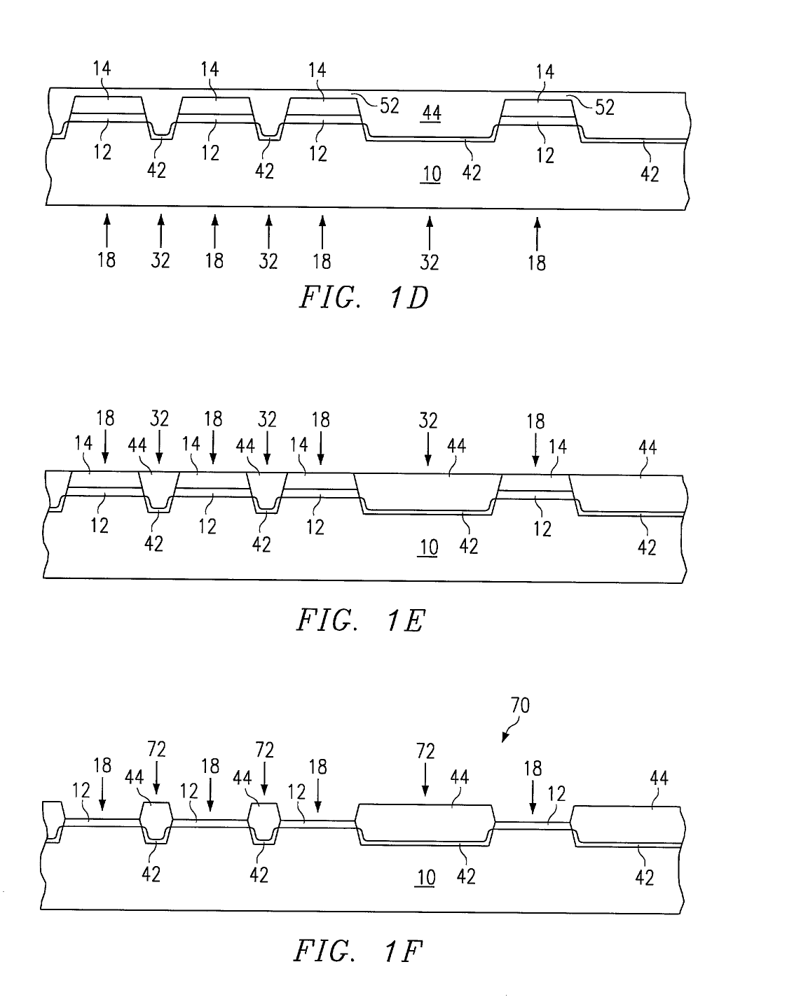

FIGS. 1A-1F illustrate a process for forming shallow trench isolation structures in accordance with one embodiment of the present invention. The shallow trench isolation structures electrically isolate active areas in an integrated circuit. Devices are later formed in the active areas and are interconnected to complete the integrated circuit. Use of the shallow trench isolation structures allows sub 0.5 micron size devices in the integrated circuit.

Referring to FIG. 1A, a substrate 10 is provided on which shallow trench isolation structures and active areas will be formed. Substrate 10 may be any suitable semiconductor material. For example, substrate 10 may be a silicon wafer, a GaAs wafer, an SOI wafer, or a silicon wafer with previously fabricated embedded devices.

An etch stop layer 12 is formed outwardly from substrate 10. As described in more detail below, etch stop layer 12 acts as an etch stop during formation of active areas on substrate 10. In an exemplary embodiment, etch stop layer 12 comprises a pad oxide layer on the order of 200 angstroms in thickness. After formation of shallow trench isolation structures, the pad oxide remains on the active areas to facilitate formation of devices in the active areas.

A polish stop layer 14 is deposited outwardly from etch stop layer 12. As described in more detail below, polish stop layer 14 acts as a polish stop to a chemical mechanical polishing (CMP) process during formation of shallow trench isolation structures. In an exemplary embodiment, polish stop layer 14 comprises a silicon nitride layer on the order of 2,000 angstroms in thickness.

A patterned resist layer 16 is formed outwardly from polish stop layer 14 by depositing and patterning a resist material. Patterned resist layer 16 is formed so as to expose field regions in which shallow trench isolation structures will be formed. In an exemplary embodiment, the resist material used to form patterned resist layer 16 is deposited using a spin-on technique. However, any suitable deposition method may be used. Patterned resist layer 16 may be comprised of any suitable material and may have a thickness on the order of 10,000 angstroms. Patterned resist layer 16 is patterned using conventional techniques leaving patterned resist layer 16 above each active area 18 on substrate 10. The process of patterning patterned resist layer 16 also results in windows 20 exposing field areas of the integrated circuit to be formed on substrate 10. Windows 20 will eventually contain shallow trench isolation structures for isolating the active areas 18 of the integrated circuit to be formed on substrate 10.

Referring to FIG. 1B, isolation trenches 32 are formed in the field region by etching polish stop layer 14, etch stop layer 12, and a portion of substrate 10 through windows 20 in patterned resist layer 16. Conventional etch techniques are used. During the etch process, the windows 20 in patterned resist layer 16 form a resist mask. The resist mask protects active areas 18. The etch is timed to provide a desired depth for the isolation trenches 32. In the exemplary embodiment, isolation trenches 32 are etched 3,000 angstroms to 5,000 angstroms into substrate 10 yielding a total depth of isolation trenches 32 between 5,000 and 7,000 angstroms. Isolation trenches 32 correspond to the field areas of substrate 10.

Referring to FIG. 1C, a substrate prepared for formation of shallow trench isolation structures is generally indicated at 40. In order to protect substrate 10 and to provide a surface on which isolation trench structures can be formed, a thermal liner 42 is formed in each isolation trench 32. Thermal liner 42 lines the etched portion of substrate 10 and reduces any defects or deformities formed on substrate 10 by the etch process used during formation of isolation trenches 32. The thermal liner 42 may merge with the etch stop layer 12 at the edge of isolation trench 32 thereby providing an optimal rounding of the active area perimeter 18. Rounding of the active area perimeter 18 helps protect the substrate 10 from being exposed during later processing. In the exemplary embodiment, thermal liner 42 is a thermally grown silicon dioxide formed to a thickness on the order of 250 angstroms.

An insulation layer 44 is formed outwardly from the topography formed on substrate 10. Insulation layer 44 provides electrical insulation material for the shallow trench isolation structures formed in isolation trenches 32. Insulation layer 44 conforms to the topography formed on substrate 10 and, therefore, has an irregular outer surface that generally imitates the topography of the underlying structure. In the exemplary embodiment, insulation layer 44 is a refill oxide deposited to a depth of 7,000 to 10,000 angstroms depending on the trench depth.

A planarization layer 46 is formed outwardly of the insulation layer 44. Planarization layer 46 provides a substantially planar surface for final formation of isolation trench structures. The materials of insulation layer 44 and planarization layer 46 should be chosen such that they may be etched at substantially the same rate. As described in more detail below, a matched etch process allows even removal of insulation layer 44 and planarization layer 46 in formation of shallow trench isolation structures without damage to the polish stop layer 14. In the exemplary embodiment, the etch rate of planarization layer 46 and the etch rate of insulation layer 44 are within ten percent of each other. Preferably, the etch rates are matched within five percent.

In the exemplary embodiment, planarization layer 46 is a resist etch back material that is deposited using a spin-on technique. The spin-on technique distributes the planarization layer 46 material and, due to centrifugal force, provides a generally planar surface. The resist etch back plasma etch may also be referred to as a matched etch process since the etch rate of planarization layer 46 and insulation layer 44 are matched such that a generally planar surface remains after exposure to the resist etch back plasma etch. The thickness of the insulating material on top of active area 18 left after the matched etch process, or CMP depth 52, is chosen so as to provide a minimal amount of material on which a CMP process may be used to expose the silicon nitride top layer 14 of active areas 18. Although the material used for planarization layer 46 is described here as a resist etch back material, any suitable planarizing material such as polyimide with an etch rate suitably matched to the material used for insulation layer 44 may be used. If the etch rates of the planarization layer 46 and the insulating material of insulation layer 44 can be perfectly matched, then the matched etch may be done so as to stop on the polished stop layer 14 and the CMP process may be omitted.

Referring to FIG. 1D, an excess portion of insulation layer 44 and planarization layer 46 is removed by a matched etch process to a CMP depth 52. The matched etched process may be any suitable etching technique that etches both insulation layer 44 and planarization layer 46 at a rate within ten percent of each other. The CMP depth 52 is a depth at which a CMP process will be used to remove the remaining insulation layer 44 to the polish stop layer 14.

In the exemplary embodiment, a resist etch back plasma etch is used to remove planarization layer 46 and insulation layer 44 down to the CMP depth 52. In this embodiment, CMP depth 52 is 1,000 angstroms to 1,500 angstroms above polish stop layer 14 above active areas 18. Although the process is described as using a resist etch back plasma etch, any suitable etching technique may be used such that planarization layer 46 and insulation layer 44 are etched at approximately the same rate.

Referring to FIG. 1E, discrete shallow trench isolation structures are formed by removing the remaining insulation layer 44 over the active areas 18. A CMP process is used to polish away the remaining insulation layer 44 material to expose polish stop layer 14 on the top of active areas 18. During the CMP process, the polish stop layer 14 provides a stopping point for the CMP process. Once polish stop layer 14 is exposed, the CMP process is complete and a planar surface exists on the outer surface of substrate 10.

Referring to FIG. 1F, the final formation of the discrete shallow trench isolation structures is generally indicated at 70. The polish stop layer 14 is removed over the active areas 18 leaving insulation layer 44 and isolation trenches 32 to form shallow trench isolation structures 72. The field areas of substrate 10 now contain a shallow trench isolation structure 72 in each field area on substrate 10. Shallow trench isolation structures 72 provide electrical isolation for integrated circuit components using a sub 0.5 micron process.

In the exemplary embodiment, a conventional etch process is used to selectively remove polish stop layer 14 over each active area 18. In this embodiment, the etch process is a hot phosphoric etch process. This process exposes etch stop layer 12 on each active area prepared for future formation of integrated circuit components.

Thus, it is apparent that there has been provided in accordance with the present invention, a method for forming shallow trench isolation structure that satisfies the advantages set forth above such as removing excess oxide without a photolithography process. Although the present invention and its advantages have been described in detail, it should be understood that various changes, substitutions, and alterations may be readily apparent to those skilled in the art and may be made without departing from the spirit and the scope of the present invention as defined by the following claims.

What is claimed is:

1. A method for forming shallow trench isolation structures, comprising:
forming a plurality of isolation trenches in a substrate, the isolation trenches separating active areas;
forming an insulation layer outwardly from the substrate, the insulation layer filling the isolation trenches and covering the active areas;
forming a planarization layer outwardly from the insulation layer; and
removing the planarization layer and the insulation layer down to a polished stop for the active areas.

2. The method of claim 1, wherein removing the planarization layer and the insulation layer further comprises:
etching through the planarization layer and the insulation layer together at a substantially even rate down to a chemical mechanical polishing (CMP) depth outward from the active areas; and
chemically-mechanically polishing from the CMP depth down to the polish stop for the active areas.

3. The method of claim 2, further comprising etching through the planarization layer and the insulation layer at the substantially even rate using a matched etch process that etches the planarization layer and the insulation layer at rates that differ by ten percent or less.

4. The method of claim 3, wherein the matched etch comprises a resist etch back plasma etch.

5. The method of claim 2, further comprising etching through the planarization layer and the insulation layer at the substantially even rate using a matched etch process that etches the planarization layer and the insulation layer at rates that differ by five percent or less.

6. The method of claim 1, wherein the polish stop comprises a polish stop layer disposed outwardly of the active areas and further comprising removing the polish stop layer following the removal of the planarization layer and the insulation layer.

7. The method of claim 6, further comprising etching a surface of the substrate to selectively remove the polish stop layer thereby forming active areas separated by isolation trench structures formed in the isolation trenches.

8. The method of claim 6, wherein the polish stop layer comprises silicon nitride.

9. The method of claim 1, wherein the insulation layer comprises silicon oxide.

10. The method of claim 1, wherein the planarization layer comprises a resist material.

11. The method of claim 2, wherein the CMP depth is between 1,000 and 1,500 angstroms above the polish stop.

12. The method of claim 1, wherein the insulation layer is conformal.

13. A method for forming an integrated circuit, comprising:
forming a plurality of isolation trenches in a substrate, the isolation trenches separating active areas;
forming an insulation layer outwardly from the substrate, the insulation layer filling the isolation trenches and covering the active areas;
forming a planarization layer outwardly from the insulation layer;
etching through the planarization layer and the insulation layer together at a substantially even rate down to a chemical mechanical polishing (CMP) depth outward from the active areas;
chemically-mechanically polishing from the CMP depth down to a polish stop for the active areas; and
forming integrated circuit devices in the active areas to form an integrated circuit on the substrate.

14. The method of claim 13, further comprising etching through the planarization layer and the insulation layer at the substantially even rate using a matched etch process that etches the planarization layer and the insulation layer at rates that differ by ten percent or less.

15. The method of claim 13, further comprising etching through the planarization layer and the insulation layer at the substantially even rate using a matched etch process that etches the planarization layer and the insulation layer at rates that differ by five percent or less.

16. The method of claim 13, wherein the matched etch comprises a resist etch back plasma etch.

17. The method of claim 13, wherein the polish stop comprises a polish stop layer disposed outwardly of the active areas and further comprising removing the polish stop layer following the chemical-mechanical polishing process.

18. The method of claim 13, wherein the insulation layer comprises silicon oxide.

19. The method of claim 13, wherein the planarization layer comprises a resist material.

20. The method of claim 13, wherein the CMP depth is between 1,000 and 1,500 angstroms above the polish stop.

21. A method for forming shallow trench isolation structures, comprising:
forming a plurality of isolation trenches in a substrate, the isolation trenches separating active areas of the substrate;
forming an insulation layer outwardly from the substrate, the insulation layer filling the isolation trenches and covering the active areas;
forming a planarization layer outwardly from the insulation layer;
etching through the planarization layer and the insulation layer together at a substantially even rate down to an intermediate level with 1500 angstroms of a polish stop for the active areas using a matched etch process that etches the planarization layer and the insulation layer at rates that differ by ten percent or less; and
chemically-mechanically polishing from the intermediate level down to the polish stop for the active areas of the substrate.
